(19) United States
(12) Patent Application Publication
(10) Pub. No.: US 2025/0344521 A1
(43) Pub. Date: Nov. 6, 2025

(54) SEMICONDUCTOR DEVICE AND METHOD OF MAKING

(71) Applicant: Taiwan Semiconductor Manufacturing Company Limited, Hsin-Chu (TW)

(72) Inventors: Wen-Sheng WANG, Hsin-Chu (TW); Yi-Hsuan FAN, New Taipei City (TW); Hsuan-Hao CHU, Taipei City (TW); Ian HONG, Hsinchu County (TW)

(21) Appl. No.: 18/654,173

(22) Filed: May 3, 2024

(51) Int. Cl. H10F 30/223; H10F 71/00

(52) U.S. Cl. CPC H10F 30/223; H10F 71/121

(57) ABSTRACT

A semiconductor device is provided. The semiconductor device includes a poly layer. The semiconductor device includes a substrate over the poly layer. The semiconductor device includes an epitaxial layer over the substrate. The semiconductor device includes a photodiode in the epitaxial layer.

### BACKGROUND

Semiconductor devices are used in a multitude of electronic devices, such as mobile phones, laptops, desktops, tablets, watches, gaming systems, and various other industrial, commercial, and consumer electronics. Semiconductor devices generally comprise semiconductor portions and wiring portions formed inside the semiconductor portions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a semiconductor device at a stage of fabrication, in accordance with some embodiments.

FIG. 2 illustrates a cross-sectional view of a semiconductor device at a stage of fabrication, in accordance with some embodiments.

FIG. 3 illustrates a cross-sectional view of a semiconductor device at a stage of fabrication, in accordance with some embodiments.

FIG. 4 illustrates a cross-sectional view of a semiconductor device at a stage of fabrication, in accordance with some embodiments.

FIG. 5 illustrates a cross-sectional view of a semiconductor device at a stage of fabrication, in accordance with some embodiments.

FIG. 6 illustrates a cross-sectional view of a semiconductor device at a stage of fabrication, in accordance with some embodiments.

FIG. 7 illustrates a cross-sectional view of a semiconductor device at a stage of fabrication, in accordance with some embodiments.

FIG. 8 illustrates a cross-sectional view of a semiconductor device at a stage of fabrication, in accordance with some embodiments.

FIG. 9 illustrates a cross-sectional view of a semiconductor device at a stage of fabrication, in accordance with some embodiments.

FIG. 10 illustrates a cross-sectional view of a semiconductor device at a stage of fabrication, in accordance with some embodiments.

FIG. 11 illustrates a cross-sectional view of a semiconductor device at a stage of fabrication, in accordance with some embodiments.

FIG. 12 illustrates a cross-sectional view of a semiconductor device at a stage of fabrication, in accordance with some embodiments.

FIG. 13 illustrates a cross-sectional view of a semiconductor device, in accordance with some embodiments.

FIG. 14 illustrates a cross-sectional view of a semiconductor device, in accordance with some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

A semiconductor device has a poly layer, a substrate over the poly layer, a plurality of epitaxial layers over the substrate, and a photodiode in the plurality of epitaxial layers. The plurality of epitaxial layers includes dopants of a first conductivity type. The photodiode includes a first doped region having a second conductivity type different than the first conductivity type. The photodiode includes a second doped region, over the first doped region, having the first conductivity type. As compared with a device that does not include the poly layer, the poly layer provides for a reduced amount of metal contaminants in at least one of (i) the photodiode or (ii) at least a portion of the plurality of epitaxial layers. In some embodiments, the semiconductor device operates as an image sensor. The reduced amount of metal contaminants provides for at least one of improved accuracy, reduced noise, increased sensitivity, improved white pixel performance, etc. of the image sensor. It is to be appreciated that while metal contaminants are mentioned herein any contaminants are contemplated and thus limitation to metal contaminants is not intended. Where suitable, metal contaminants can thus simply be regarded as contaminants.

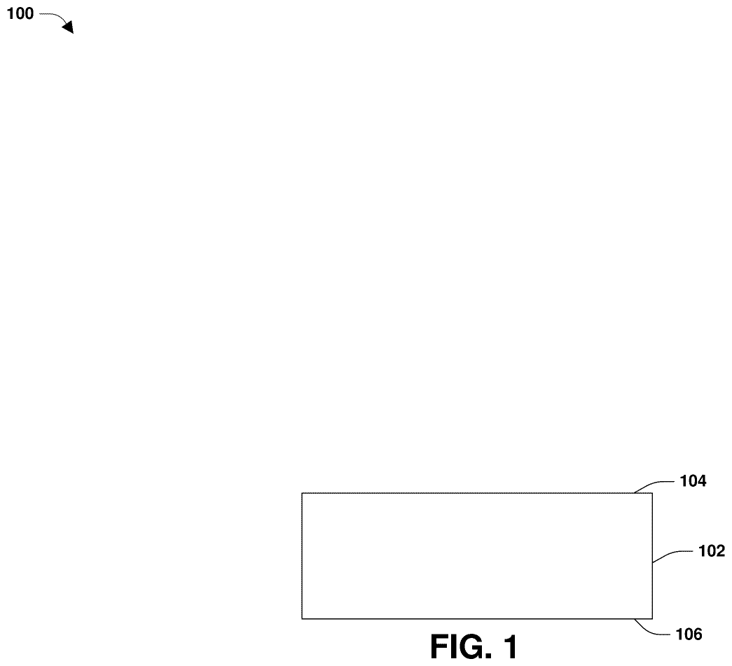

FIGS. 1-12 illustrate cross-sectional views of a semiconductor device 100 at various stages of fabrication, in accordance with some embodiments. In some embodiments, a sensor is implemented via the semiconductor device 100. The sensor comprises at least one of an image sensor, a complementary metal-oxide-semiconductor (CMOS) image sensor, a backside CMOS image sensor, or another type of sensor. Other structures and/or configurations of the semiconductor device 100 and/or the sensor are within the scope of the present disclosure.

FIG. 1 illustrates the semiconductor device 100 according to some embodiments. The semiconductor device 100 comprises a substrate 102. The substrate 102 comprises at least one of an epitaxial layer, a silicon-on-insulator (SOI) structure, a wafer, or a die formed from a wafer. The substrate 102 has a first side 104 and a second side 106 opposing the first side 104. The substrate 102 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The substrate 102 comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the substrate 102 are within the scope of the present disclosure.

In some embodiments, the substrate 102 comprises first dopants having a first conductivity type, such as n-type or p-type. In some embodiments, the first dopants comprise at least one of nitrogen (N), phosphorus (P), beryllium (Be), boron (B), aluminum (Al), gallium (Ga), or other dopant. In some embodiments, the first dopants are p-type dopants comprising at least one of boron dopants, aluminum dopants, gallium dopants, beryllium dopants, or other p-type dopants. In some embodiments, the first dopants are n-type dopants comprising at least one of nitrogen dopants, phosphorus dopants, or other n-type dopants. In some embodiments, the substrate 102 is doped with the first dopants by at least one of ion implantation, molecular diffusion, or other suitable techniques. In some embodiments, a depth of dopants of the first dopants in the substrate 102 is controlled by increasing or decreasing a voltage, energy, etc. used to direct the dopants into the substrate 102. In some embodiments, a first dopant concentration of the first dopants in the substrate 102 is controlled by at least one of a quantity of implantation shots of one or more implantation shots performed to direct the first dopants into the substrate 102, an implantation dose an implantation shot of the one or more implantation shots, an implantation energy level of the implantation shot, or other suitable parameter.

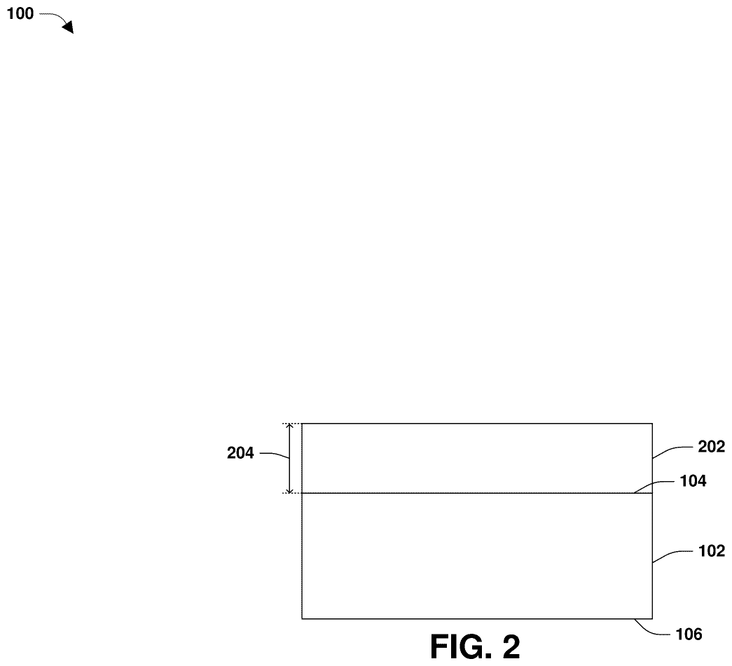

FIG. 2 illustrates a poly layer 202, such as a backside poly layer, formed over the substrate 102, according to some embodiments. In some embodiments, the poly layer 202 is formed at the first side 104 of the substrate 102. In some embodiments, the poly layer 202 is in direct contact with the first side 104 of the substrate 102. In some embodiments, the poly layer 202 is in indirect contact with the first side 104 of the substrate 102, where one or more layers, such as a buffer layer, are between the poly layer 202 and the substrate 102. The poly layer 202 is formed by at least one of physical vapor deposition (PVD), sputtering, chemical vapor deposition (CVD), plasma enhanced CVD (PECVD), low pressure CVD (LPCVD), atomic layer chemical vapor deposition (ALCVD), ultrahigh vacuum CVD (UHVCVD), reduced pressure CVD (RPCVD), atomic layer deposition (ALD), molecular beam epitaxy (MBE), liquid phase epitaxy (LPE), spin on, growth, or other suitable techniques. The poly layer 202 comprises at least one of polysilicon or other suitable material. A thickness 204 of the poly layer 202 is at least one of (i) at least about 500 angstroms, or (ii) at least about 1000 angstroms. Other values of the thickness 204 are within the scope of the present disclosure.

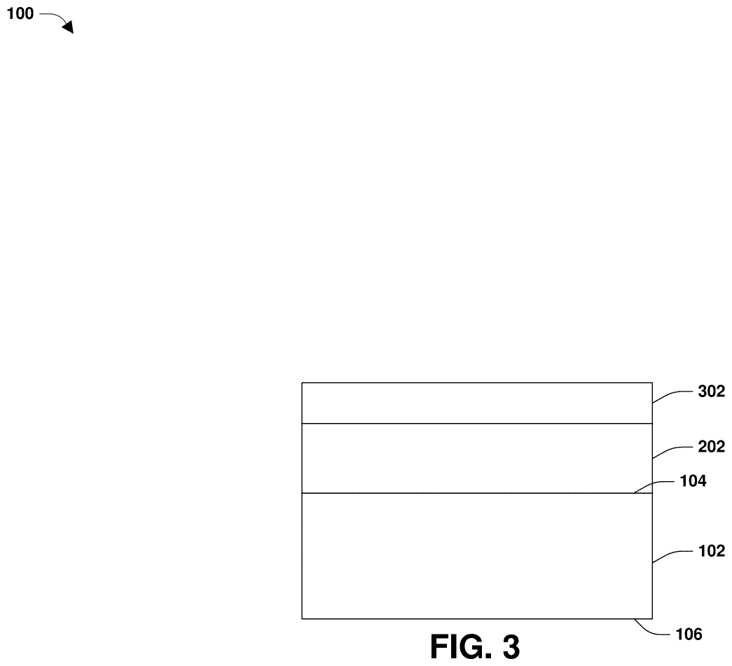

FIG. 3 illustrates an oxide layer 302, such as a backside oxide layer 302, formed over the poly layer 202, according to some embodiments. The oxide layer 302 is formed by at least one of PVD, sputtering, CVD, PECVD, LPCVD, ALCVD, UHVCVD, RPCVD, ALD, MBE, LPE, spin on, growth, or other suitable techniques. The oxide layer 302 comprises at least one of an oxide semiconductor material, such as silicon oxide, or other suitable material.

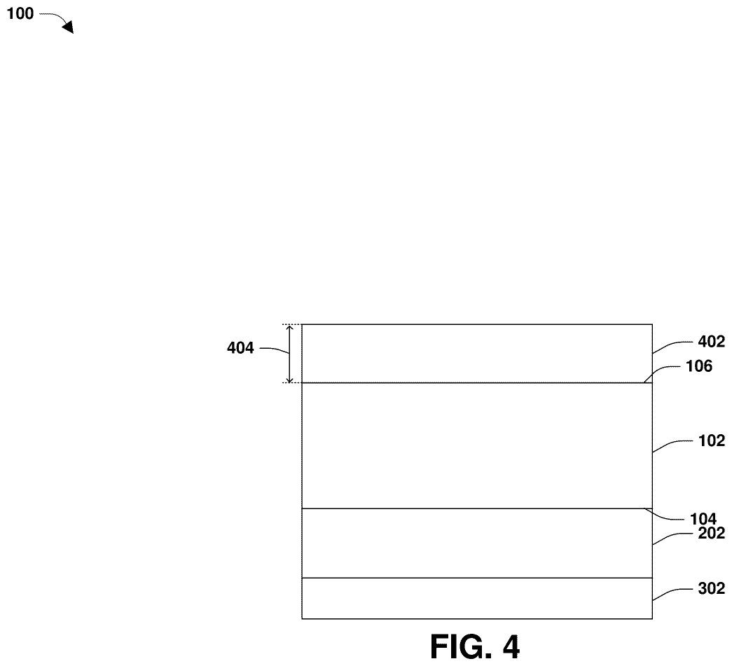

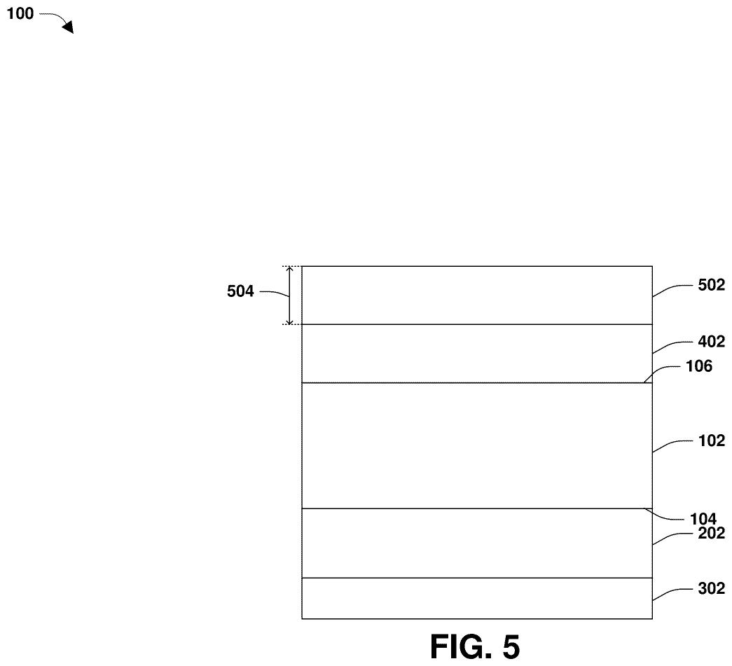

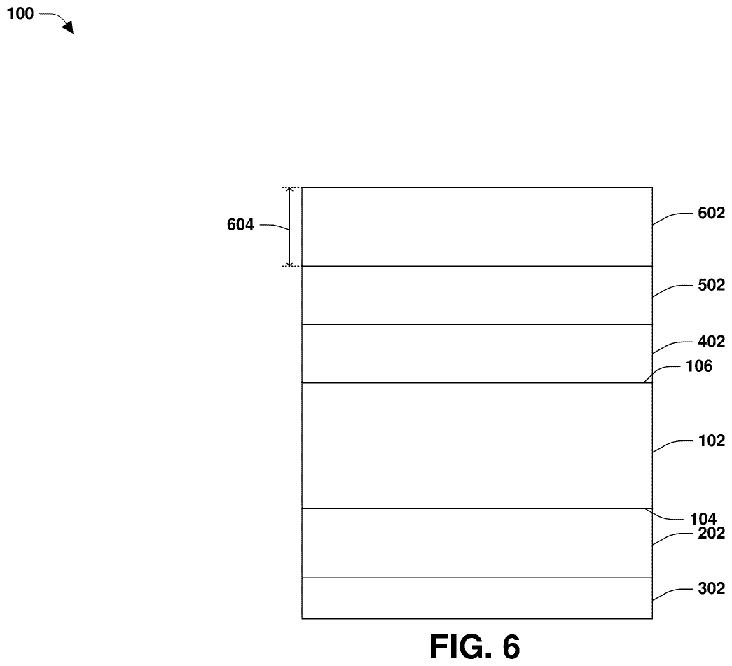

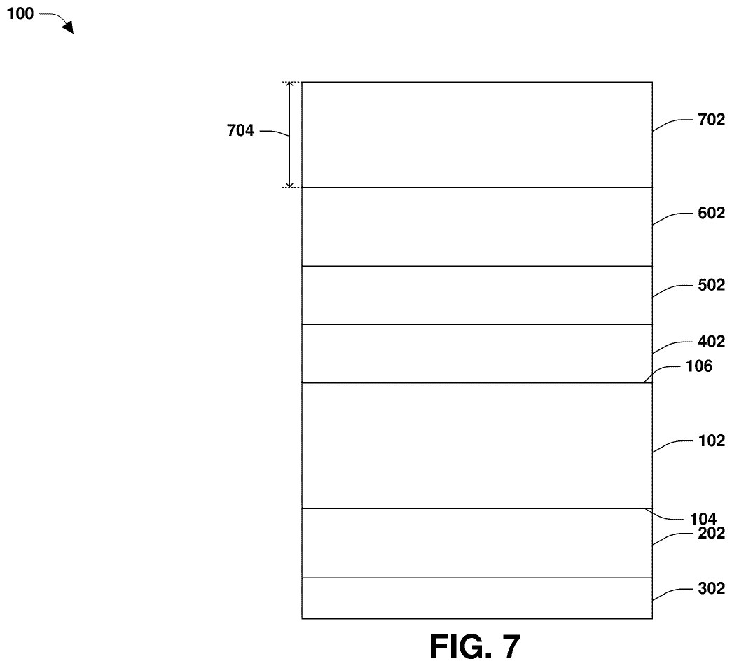

In some embodiments, a plurality of epitaxial layers is formed over the substrate 102. In some embodiments, the plurality of epitaxial layers is formed at the second side 106 of the substrate 102. In some embodiments, the plurality of epitaxial layers comprise at least one of a first epitaxial layer 402 (shown in FIG. 4), a second epitaxial layer 502 (shown in FIG. 5), a third epitaxial layer 602 (shown in FIG. 6), a fourth epitaxial layer 702 (shown in FIG. 7), or other epitaxial layer. In some embodiments, prior to forming one, some or all of the plurality of epitaxial layers, an inversion operation is performed such that at least one of (i) the oxide layer 302 is the bottommost layer of the semiconductor device 100, or (ii) the poly layer 202 and the substrate 102 are over the oxide layer 302.

FIG. 4 illustrates the first epitaxial layer 402 formed over the substrate 102, according to some embodiments. In some embodiments, the first epitaxial layer 402 is formed to have a first thickness 404. In some embodiments, the first epitaxial layer 402 is formed by a first epitaxial process, such as an epitaxial growth process. In some embodiments, the first epitaxial process includes at least one of molecular beam epitaxy, CVD, vapor-phase epitaxy (VPE), ultra-high vacuum CVD (UHV-CVD), growth, or other suitable process. In some embodiments, the first epitaxial process uses one or more precursors comprising at least one of a gas precursor, a vapor precursor, or a liquid precursor. In some embodiments, the one or more precursors interact with the substrate 102 during the first epitaxial process. Embodiments are contemplated in which the first epitaxial layer 402 is formed by at least one of PVD, sputtering, CVD, PECVD, LPCVD, ALCVD, UHVCVD, RPCVD, ALD, MBE, LPE, spin on, growth, or other suitable techniques.

In some embodiments, the first epitaxial layer 402 is a doped layer, such as a doped epi layer. In some embodiments, the first epitaxial layer 402 comprises second dopants having the first conductivity type. In some embodiments, in the first epitaxial process, at least some of the second dopants having the first conductivity type travel from the substrate 102 to the first epitaxial layer 402. In some embodiments, at least some of the second dopants are introduced to the first epitaxial layer 402 via the first epitaxial process by at least one of (i) adding impurities to a source material of the first epitaxial process, (ii) using a dopant precursor in the first epitaxial process, or (iii) other suitable techniques. In some embodiments, at least some of the second dopants are introduced to the first epitaxial layer 402 after the first epitaxial process is performed, such as by at least one of ion implantation, molecular diffusion, or other suitable techniques.

In some embodiments, the first epitaxial layer 402 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. In some embodiments, the first epitaxial layer 402 is in direct contact with the second side 106 of the substrate 102. The first epitaxial layer 402 is different than the substrate 102, such as having a different material composition, such that an interface is defined between the first epitaxial layer 402 and the substrate 102. In some embodiments, the first epitaxial layer 402 does not have a material composition different than the substrate 102. An interface is nevertheless defined between the first epitaxial layer 402 and the substrate 102 because the first epitaxial layer 402 and the substrate 102 are separate, different, etc. layers (e.g., one or more measurable properties exist at the interface that would not exist and/or would have different values in a continuous, single, etc. layer (e.g., roughness, smoothness, tension, compression, conductivity, resistivity, etc.)). In some embodiments, the first epitaxial layer 402 is in indirect contact with the second side 106 of the substrate 102, where one or more layers, such as a buffer layer, are between the first epitaxial layer 402 and the substrate 102. In some embodiments, a second dopant concentration of the second dopants in the first epitaxial layer 402 is less than the first dopant concentration of the first dopants in the substrate 102. In some embodiments, the second dopant concentration is controlled by at least one of a parameter of the first epitaxial process or other suitable parameter.

FIG. 5 illustrates the second epitaxial layer 502 formed over the first epitaxial layer 402, according to some embodiments. In some embodiments, the second epitaxial layer 502 is formed to have a second thickness 504. In some embodiments, the second thickness 504 is greater than the first thickness 404 of the first epitaxial layer 402. In some embodiments, the second epitaxial layer 502 is formed by a second epitaxial process, such as an epitaxial growth process. In some embodiments, the second epitaxial process includes at least one of molecular beam epitaxy, CVD, VPE, UHV-CVD, growth, or other suitable process. In some embodiments, the second epitaxial process uses one or more precursors comprising at least one of a gas precursor, a vapor precursor, or a liquid precursor. In some embodiments, the one or more precursors interact with at least one of the first epitaxial layer 402 or the substrate 102 during the second epitaxial process. Embodiments are contemplated in which the second epitaxial layer 502 is formed by at least one of PVD, sputtering, CVD, PECVD, LPCVD, ALCVD, UHVCVD, RPCVD, ALD, MBE, LPE, spin on, growth, or other suitable techniques.

In some embodiments, the second epitaxial layer 502 is a doped layer, such as a doped epi layer. In some embodiments, the second epitaxial layer 502 comprises third dopants having the first conductivity type. In some embodiments, in the second epitaxial process, at least some of the third dopants having the first conductivity type travel from at least one of the first epitaxial layer 402 or the substrate 102 to the second epitaxial layer 502. In some embodiments, at least some of the third dopants are introduced to the second epitaxial layer 502 via the second epitaxial process by at least one of (i) adding impurities to a source material of the second epitaxial process, (ii) using a dopant precursor in the second epitaxial process, or (iii) other suitable techniques. In some embodiments, at least some of the third dopants are introduced to the second epitaxial layer 502 after the second epitaxial process is performed, such as by at least one of ion implantation, molecular diffusion, or other suitable techniques.

In some embodiments, the second epitaxial layer 502 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. In some embodiments, the second epitaxial layer 502 is in direct contact with a top surface of the first epitaxial layer 402. The second epitaxial layer 502 is different than the first epitaxial layer 402, such as having a different material composition, such that an interface is defined between the second epitaxial layer 502 and the first epitaxial layer 402. In some embodiments, the second epitaxial layer 502 does not have a material composition different than the first epitaxial layer 402. An interface is nevertheless defined between the second epitaxial layer 502 and the first epitaxial layer 402 because the second epitaxial layer 502 and the first epitaxial layer 402 are separate, different, etc. layers (e.g., one or more measurable properties exist at the interface that would not exist and/or would have different values in a continuous, single, etc. layer (e.g., roughness, smoothness, tension, compression, conductivity, resistivity, etc.)). In some embodiments, the second epitaxial layer 502 is in indirect contact with the top surface of the first epitaxial layer 402, where one or more layers, such as a buffer layer, are between the second epitaxial layer 502 and the first epitaxial layer 402. In some embodiments, a third dopant concentration of the third dopants in the second epitaxial layer 502 is less than the second dopant concentration of the second dopants in the first epitaxial layer 402. In some embodiments, the third dopant concentration is controlled by at least one of a parameter of the second epitaxial process or other suitable parameter.

FIG. 6 illustrates the third epitaxial layer 602 formed over the second epitaxial layer 502, according to some embodiments. In some embodiments, the third epitaxial layer 602 is formed to have a third thickness 604. In some embodiments, the third thickness 604 is greater than the second thickness 504 of the second epitaxial layer 502. In some embodiments, the third epitaxial layer 602 is formed by a third epitaxial process, such as an epitaxial growth process. In some embodiments, the third epitaxial process includes at least one of molecular beam epitaxy, CVD, VPE, UHV-CVD, growth, or other suitable process. In some embodiments, the third epitaxial process uses one or more precursors comprising at least one of a gas precursor, a vapor precursor, or a liquid precursor. In some embodiments, the one or more precursors interact with at least one of the second epitaxial layer 502, the first epitaxial layer 402, or the substrate 102 during the third epitaxial process. Embodiments are contemplated in which the third epitaxial layer 602 is formed by at least one of PVD, sputtering, CVD, PECVD, LPCVD, ALCVD, UHVCVD, RPCVD, ALD, MBE, LPE, spin on, growth, or other suitable techniques.

In some embodiments, the third epitaxial layer 602 is a doped layer, such as a doped epi layer. In some embodiments, the third epitaxial layer 602 comprises fourth dopants having the first conductivity type. In some embodiments, in the third epitaxial process, at least some of the fourth dopants having the first conductivity type travel from at least one of the second epitaxial layer 502, the first epitaxial layer 402, or the substrate 102 to the third epitaxial layer 602. In some embodiments, at least some of the fourth dopants are introduced to the third epitaxial layer 602 via the third epitaxial process by at least one of (i) adding impurities to a source material of the third epitaxial process, (ii) using a dopant precursor in the third epitaxial process, or (iii) other suitable techniques. In some embodiments, at least some of the fourth dopants are introduced to the third epitaxial layer 602 after the third epitaxial process is performed, such as by at least one of ion implantation, molecular diffusion, or other suitable techniques.

In some embodiments, the third epitaxial layer 602 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. In some embodiments, the third epitaxial layer 602 is in direct contact with a top surface of the second epitaxial layer 502. The third epitaxial layer 602 is different than the second epitaxial layer 502, such as having a different material composition, such that an interface is defined between the third epitaxial layer 602 and the second epitaxial layer 502. In some embodiments, the third epitaxial layer 602 does not have a material composition different than the second epitaxial layer 502. An interface is nevertheless defined between the third epitaxial layer 602 and the second epitaxial layer 502 because the third epitaxial layer 602 and the second epitaxial layer 502 are separate, different, etc. layers (e.g., one or more measurable properties exist at the interface that would not exist and/or would have different values in a continuous, single, etc. layer (e.g., roughness, smoothness, tension, compression, conductivity, resistivity, etc.)). In some embodiments, the third epitaxial layer 602 is in indirect contact with the top surface of the second epitaxial layer 502, where one or more layers, such as a buffer layer, are between the third epitaxial layer 602 and the second epitaxial layer 502. In some embodiments, a fourth dopant concentration of the fourth dopants in the third epitaxial layer 602 is less than the third dopant concentration of the third dopants in the second epitaxial layer 502. In some embodiments, the fourth dopant concentration is controlled by at least one of a parameter of the third epitaxial process or other suitable parameter.

FIG. 7 illustrates the fourth epitaxial layer 702 formed over the third epitaxial layer 602, according to some embodiments. In some embodiments, the fourth epitaxial layer 702 is formed to have a fourth thickness 704. In some embodiments, the fourth thickness 704 is greater than the third thickness 604 of the third epitaxial layer 602. In some embodiments, the fourth epitaxial layer 702 is formed by a fourth epitaxial process, such as an epitaxial growth process. In some embodiments, the fourth epitaxial process includes at least one of molecular beam epitaxy, CVD, VPE, UHV-CVD, growth, or other suitable process. In some embodiments, the fourth epitaxial process uses one or more precursors comprising at least one of a gas precursor, a vapor precursor, or a liquid precursor. In some embodiments, the one or more precursors interact with at least one of the third epitaxial layer 602, the second epitaxial layer 502, the first epitaxial layer 402, or the substrate 102 during the fourth epitaxial process. Embodiments are contemplated in which the fourth epitaxial layer 702 is formed by at least one of PVD, sputtering, CVD, PECVD, LPCVD, ALCVD, UHVCVD, RPCVD, ALD, MBE, LPE, spin on, growth, or other suitable techniques.

In some embodiments, the fourth epitaxial layer 702 is a doped layer, such as a doped epi layer. In some embodiments, the fourth epitaxial layer 702 comprises fifth dopants having the first conductivity type. In some embodiments, in the fourth epitaxial process, at least some of the fifth dopants having the first conductivity type travel from at least one of the third epitaxial layer 602, the second epitaxial layer 502, the first epitaxial layer 402, or the substrate 102 to the fourth epitaxial layer 702. In some embodiments, at least some of the fifth dopants are introduced to the fourth epitaxial layer 702 via the fourth epitaxial process by at least one of (i) adding impurities to a source material of the fourth epitaxial process, (ii) using a dopant precursor in the fourth epitaxial process, (iii) diffusion, or (iv) other suitable techniques. In some embodiments, at least some of the fifth dopants are introduced to the fourth epitaxial layer 702 after the fourth epitaxial process is performed, such as by at least one of ion implantation, molecular diffusion, or other suitable techniques.

In some embodiments, the fourth epitaxial layer 702 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. In some embodiments, the fourth epitaxial layer 702 is in direct contact with a top surface of the third epitaxial layer 602. The fourth epitaxial layer 702 is different than the third epitaxial layer 602, such as having a different material composition, such that an interface is defined between the fourth epitaxial layer 702 and the third epitaxial layer 602. In some embodiments, the fourth epitaxial layer 702 does not have a material composition different than the third epitaxial layer 602. An interface is nevertheless defined between the fourth epitaxial layer 702 and the third epitaxial layer 602 because the fourth epitaxial layer 702 and the third epitaxial layer 602 are separate, different, etc. layers (e.g., one or more measurable properties exist at the interface that would not exist and/or would have different values in a continuous, single, etc. layer (e.g., roughness, smoothness, tension, compression, conductivity, resistivity, etc.)). In some embodiments, the fourth epitaxial layer 702 is in indirect contact with the top surface of the third epitaxial layer 602, where one or more layers, such as a buffer layer, are between the fourth epitaxial layer 702 and the third epitaxial layer 602. In some embodiments, a fifth dopant concentration of the fifth dopants in the fourth epitaxial layer 702 is less than the fourth dopant concentration of the fourth dopants in the third epitaxial layer 602. In some embodiments, the fifth dopant concentration is controlled by at least one of a parameter of the fourth epitaxial process or other suitable parameter.

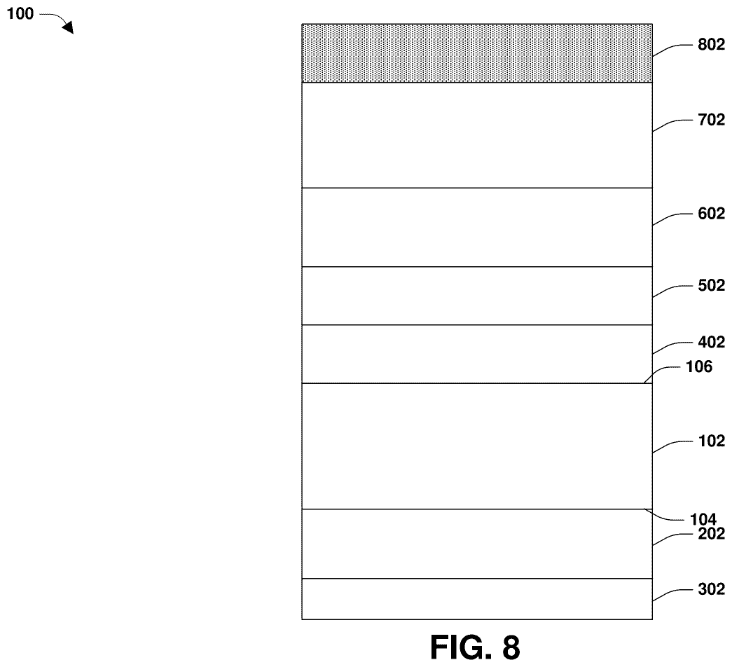

FIG. 8 illustrates a first photoresist 802 formed over the fourth epitaxial layer 702, according to some embodiments. The first photoresist 802 at least one of overlies the fourth epitaxial layer 702, is in direct contact with a top surface of the fourth epitaxial layer 702, or is in indirect contact with the top surface of the fourth epitaxial layer 702. The first photoresist 802 is formed by at least one of PVD, sputtering, CVD, PECVD, LPCVD, ALCVD, UHVCVD, RPCVD, ALD, MBE, LPE, spin on, growth, or other suitable techniques.

In some embodiments, the first photoresist 802 comprises a light-sensitive material, where properties, such as solubility, of the first photoresist 802 are affected by light. The first photoresist 802 is a negative photoresist or a positive photoresist. With respect to a negative photoresist, regions of the negative photoresist become insoluble when illuminated by a light source, such that application of a solvent to the negative photoresist during a subsequent development stage removes non-illuminated regions of the negative photoresist. A pattern formed in the negative photoresist is thus a negative of a pattern defined by opaque regions of a template, such as a mask, between the light source and the negative photoresist. In a positive photoresist, illuminated regions of the positive photoresist become soluble and are removed via application of a solvent during development. Thus, a pattern formed in the positive photoresist is a positive image of opaque regions of the template, such as a mask, between the light source and the positive photoresist.

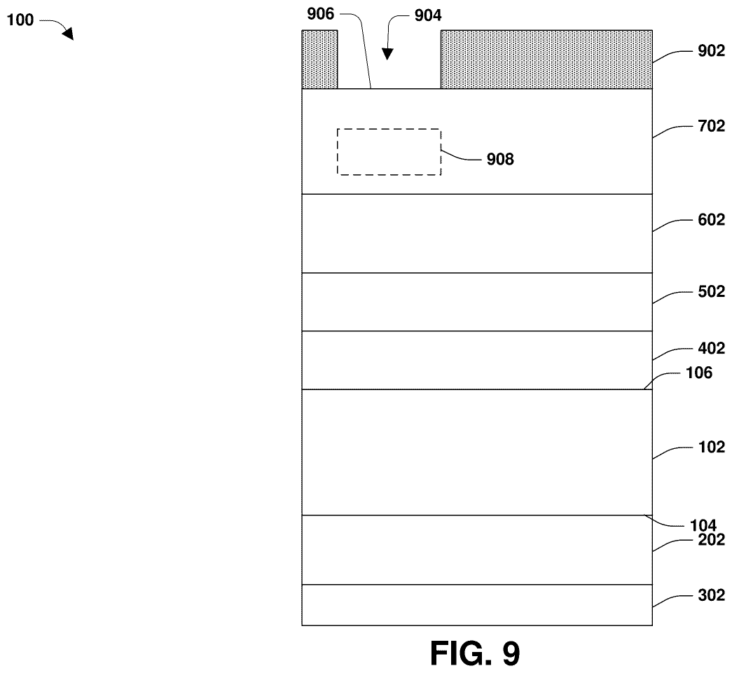

FIG. 9 illustrates a first patterned photoresist 902 is formed from the first photoresist 802, according to some embodiments. In some embodiments, the first patterned photoresist 902 defines an opening 904 exposing a portion 906 of a top surface of the fourth epitaxial layer 702. Even though one opening in the first patterned photoresist 902 is depicted, any number of openings in the first patterned photoresist 902 are contemplated.

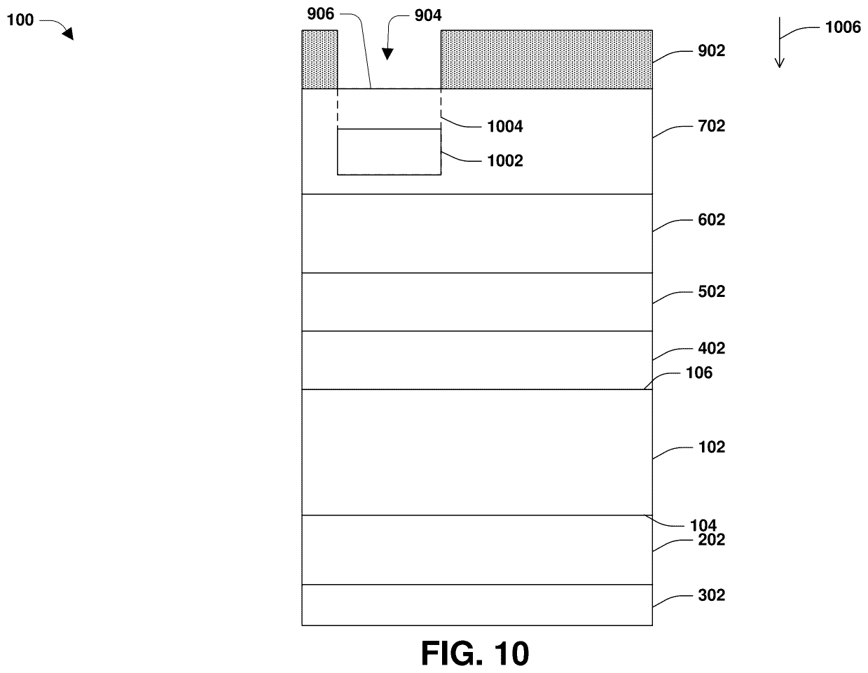

FIG. 10 illustrates use of the first patterned photoresist 902 to form a first doped region 1002 having a second conductivity type in one or more epitaxial layers of the plurality of epitaxial layers, according to some embodiments. In some embodiments, the first doped region 1002 comprises sixth dopants having the second conductivity type. In some embodiments, the first conductivity type is p-type and the second conductivity type is n-type. Embodiments are contemplated in which the first conductivity type is n-type and the second conductivity type is p-type. In some embodiments, the first patterned photoresist 902 is used to dope a region 908 (shown with a dashed-line rectangle in FIG. 9), comprising a portion of the fourth epitaxial layer 702, to form the first doped region 1002 shown in FIG. 10. In some embodiments, the region 908 is counter-doped to form the first doped region 1002. In some embodiments, the region 908 is doped to form the first doped region 1002 by a first doping process comprising at least one of ion implantation, molecular diffusion, or other suitable techniques. In some embodiments, the first doping process comprises directing dopants having the second conductivity type through one or more portions of the top surface of the fourth epitaxial layer 702 that are laterally offset from the first patterned photoresist 902. In some embodiments, the dopants are n-type dopants comprising at least one of nitrogen dopants, phosphorus dopants, or other n-type dopants. In some embodiments, the first patterned photoresist 902 blocks dopants from entering a portion of the top surface of the fourth epitaxial layer 702 that is covered by the first patterned photoresist 902. In some embodiments, the first doping process comprises directing dopants having the second conductivity type through the portion 906 of the top surface of the fourth epitaxial layer 702 exposed by the opening 904. In some embodiments, a depth to which dopants penetrate into the semiconductor device 100 in the first doping process is controlled by increasing or decreasing a voltage, power, etc. used to direct the dopants into the semiconductor device 100. Other processes and techniques for at least one of doping the region 908 or forming the first doped region 1002 are within the scope of the present disclosure. In some embodiments, the first doped region 1002 has a gradient such that a concentration of dopants changes, such as increases or decreases along a first direction 1006, such as a vertical direction along a y-axis. In some embodiments, the first doped region 1002 underlies the opening 904 in the first patterned photoresist 902.

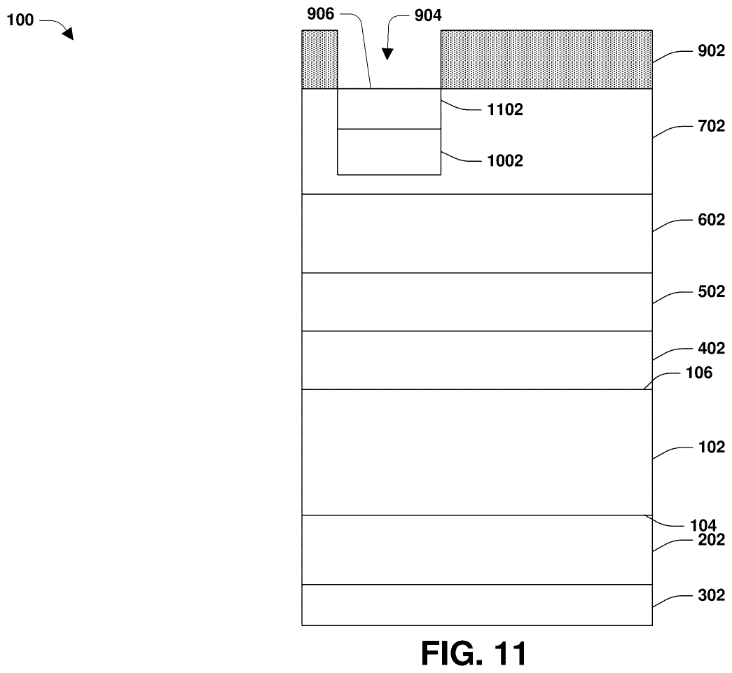

FIG. 11 illustrates use of the first patterned photoresist 902 to form a second doped region 1102 having the first conductivity type in one or more epitaxial layers of the plurality of epitaxial layers, according to some embodiments. In some embodiments, the second doped region 1102 comprises seventh dopants having the first conductivity type. In some embodiments, the first patterned photoresist 902 is used to dope a region 1004 (shown with a dashed-line rectangle in FIG. 10), comprising a portion of the fourth epitaxial layer 702, to form the second doped region 1102 shown in FIG. 11. In some embodiments, the region 1004 is doped to form the second doped region 1102 by a second doping process comprising at least one of ion implantation, molecular diffusion, or other suitable techniques. In some embodiments, the second doping process comprises directing dopants having the first conductivity type through one or more portions of the top surface of the fourth epitaxial layer 702 that are laterally offset from the first patterned photoresist 902. In some embodiments, the second doping process comprises directing dopants having the first conductivity type through the portion 906 of the top surface of the fourth epitaxial layer 702 exposed by the opening 904 into at least one of the fourth epitaxial layer 702 or one or more epitaxial layers underlying the fourth epitaxial layer 702. In some embodiments, a depth to which dopants penetrate into the semiconductor device 100 in the second doping process is controlled by increasing or decreasing a voltage, power, etc. used to direct the dopants into the semiconductor device 100. Other processes and techniques for at least one of doping the region 1004 or forming the second doped region 1102 are within the scope of the present disclosure. In some embodiments, the second doped region 1102 has a gradient such that a concentration of dopants changes, such as increases or decreases along the first direction 1006 (shown in FIG. 10). The second doped region 1102 at least one of (i) underlies the opening 904 in the first patterned photoresist 902 or (ii) overlies the first doped region 1002. In some embodiments, the second doped region 1102 is adjacent the first doped region 1002. In some embodiments, the second doped region 1102 at least one of comprises or is adjacent the portion 906 of the top surface of the fourth epitaxial layer 702.

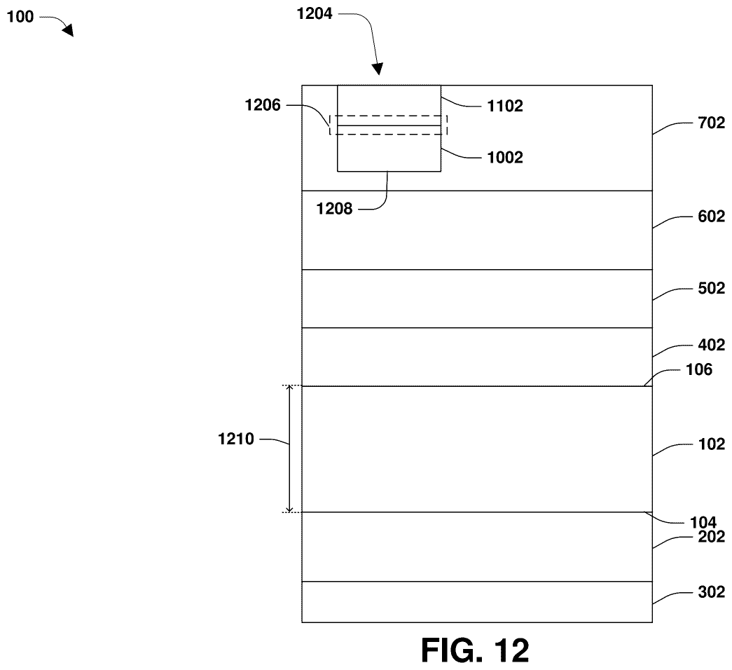

FIG. 12 illustrates removal of the first patterned photoresist 902, according to some embodiments. In some embodiments, the first patterned photoresist 902 is removed after the first doped region 1002 and the second doped region 1102 are formed. The first patterned photoresist 902 is removed by at least one of performing a washing process to wash the first patterned photoresist 902 away, stripping the first patterned photoresist 902 away, etching the first patterned photoresist 902, chemical mechanical planarization (CMP), or other suitable techniques.

In some embodiments, the first patterned photoresist 902 is removed after the first doping process performed to form the first doped region 1002 and prior to the second doping process performed to form the second doped region 1102. In some embodiments, a second patterned photoresist is formed after removing the first patterned photoresist 902. In some embodiments, the second patterned photoresist is formed using one or more of the techniques provided herein with respect to the first patterned photoresist 902. In some embodiments, the second patterned photoresist includes at least some of the features, relationships with other elements, etc. provided herein with respect to the first patterned photoresist 902. In some embodiments, the second patterned photoresist is used to form the second doped region 1102 using one or more of the techniques provided herein with respect to using the first patterned photoresist 902 to form the second doped region 1102.

Embodiments are contemplated in which a mask layer, such as a hard mask layer, is used to form at least one of the first doped region 1002 or the second doped region 1102. In some embodiments, a first mask layer (not shown) is formed over the fourth epitaxial layer 702. The first mask layer is formed by at least one of PVD, sputtering, CVD, PECVD, LPCVD, ALCVD, UHVCVD, RPCVD, ALD, MBE, LPE, spin on, growth, or other suitable techniques. In some embodiments, the first mask layer is a hard mask layer. The first mask layer comprises at least one of oxide, nitride, a metal, or other suitable material. The first mask layer is patterned to form a first patterned mask layer (not shown). In some embodiments, the first mask layer is patterned via an etching process. The etching process uses at least one of plasma, fluorine, hydrogen fluoride (HF), diluted HF, sulfur hexafluoride (SF₆), a chlorine compound such as hydrogen chloride (HCl₂), hydrogen sulfide (H₂S), tetrafluoromethane (CF₄), or other suitable material to remove one or more portions of the first mask layer to form the first patterned mask layer. In some embodiments, the first patterned mask layer includes at least some of the features, relationships with other elements, etc. provided herein with respect to the first patterned photoresist 902. In some embodiments, the first patterned mask layer is used to form the first doped region 1002 using one or more of the techniques provided herein with respect to using the first patterned photoresist 902 to form the first doped region 1002. In some embodiments, the first patterned mask layer is used to form the second doped region 1102 using one or more of the techniques provided herein with respect to using the first patterned photoresist 902 to form the second doped region 1102. In some embodiments, at least one of the first doping process or the second doping process is performed using the first patterned mask layer. In some embodiments, the first patterned mask layer is removed after the second doping process. In some embodiments, the first patterned mask layer is removed by at least one of CMP, a washing process, etching, or other suitable techniques.

In some embodiments, the first patterned mask layer is removed after the first doping process and prior to the second doping process. In some embodiments, a second patterned mask layer is formed after removing the first patterned mask layer. In some embodiments, the second patterned mask layer is formed using one or more of the techniques provided herein with respect to the first patterned mask layer. In some embodiments, the second patterned mask layer includes at least some of the features, relationships with other elements, etc. provided herein with respect to the first patterned mask layer. In some embodiments, the second patterned mask layer is used to form the second doped region 1102 using one or more of the techniques provided herein with respect to using the first patterned photoresist 902 to form the second doped region 1102.

Embodiments are contemplated in which at least some of the second doped region 1102 is formed prior to at least some of the first doped region 1002.

In some embodiments, the semiconductor device 100 comprises a p-n junction 1206 (shown in FIG. 12). In some embodiments, the p-n junction 1206 is between the first doped region 1002 and the second doped region 1102. In some embodiments, the p-n junction 1206 is formed due to the first doped region 1002 having the second conductivity type different than the first conductivity type of the second doped region 1102. Embodiments are contemplated in which the semiconductor device 100 comprises an intrinsic region (not shown) between the first doped region 1002 and the second doped region 1102, thereby forming a PIN diode structure in the p-n junction 1206.

In some embodiments, a photodiode 1204 comprises at least one of the first doped region 1002, the second doped region 1102, the p-n junction 1206, or the intrinsic region. In some embodiments, radiation is projected towards the semiconductor device 100, such as at least one of in the first direction 1006 or in a different direction. At least some of the radiation is at least one of sensed, detected, or converted to electrons by the photodiode 1204. In some embodiments, the semiconductor device 100 comprises one or more layers (not shown) overlying the fourth epitaxial layer 702. In some embodiments, the one or more layers comprise at least one of a dielectric layer, a color filter layer, a lens array, or other suitable layer. In some embodiments, the lens array comprises a lens, such as a micro-lens or other suitable lens, overlying the photodiode 1204. In some embodiments, at least some of the radiation passes through the one or more layers and is at least one of sensed, detected, or converted to electrons by the photodiode 1204.

In some embodiments, radiation is converted to electrons using the p-n junction 1206. In some embodiments, a pixel of a first image is generated based upon a first metric associated with the electrons converted by the p-n junction 1206. In some embodiments, the first metric is based upon at least one of an intensity, a charge, a current read out, etc. associated with the electrons converted by the p-n junction 1206. In some embodiments, a first read out circuit (not shown) of the semiconductor device 100 is used to measure the electrons converted using the p-n junction 1206 to determine the first metric.

Although four epitaxial layers of the plurality of epitaxial layers are shown in FIG. 12, embodiments are contemplated in which the plurality of epitaxial layers comprise any quantity of epitaxial layers, such as two epitaxial layers, three epitaxial layers, five epitaxial layers, or more than five epitaxial layers. Embodiments are contemplated in which the semiconductor device 100 comprises a single epitaxial layer in place of the plurality of epitaxial layers. Although the p-n junction 1206 is shown to be in the fourth epitaxial layer 702 in FIG. 12, embodiments are contemplated in which the p-n junction 1206 is in any of the plurality of epitaxial layers, such as the first epitaxial layer 402, the second epitaxial layer 502, or the third epitaxial layer 602. Although a side 1208 of the photodiode 1204 is shown to be in the fourth epitaxial layer 702 in FIG. 12, embodiments are contemplated in which the side 1208 of the photodiode 1204 is in any of the plurality of epitaxial layers, such as the first epitaxial layer 402, the second epitaxial layer 502, or the third epitaxial layer 602.

In some embodiments, the plurality of epitaxial layers is formed with gradient dopant concentrations associated with the first conductivity type. In some embodiments, each epitaxial layer of one, some, or all of the plurality of epitaxial layers is formed to have a lesser dopant concentration of dopants of the first conductivity type than an underlying layer, such as another epitaxial layer of the plurality of epitaxial layers that underlies the epitaxial layer. In some embodiments, at least one of (i) the first dopant concentration of the first dopants of the first conductivity type in the substrate 102 is greater than the second dopant concentration of the second dopants of the first conductivity type in the first epitaxial layer 402, (ii) the second dopant concentration of the second dopants of the first conductivity type in the first epitaxial layer 402 is greater than the third dopant concentration of the third dopants of the first conductivity type in the second epitaxial layer 502, (iii) the third dopant concentration of the third dopants of the first conductivity type in the second epitaxial layer 502 is greater than the fourth dopant concentration of the fourth dopants of the first conductivity type in the third epitaxial layer 602, or (iv) the fourth dopant concentration of the fourth dopants of the first conductivity type in the third epitaxial layer 602 is greater than the fifth dopant concentration of the fifth dopants of the first conductivity type in the fourth epitaxial layer 702. In some embodiments, the first dopants, the second dopants, the third dopants, the fourth dopants and/or the fifth dopants are the same dopants or different dopants among layers of the semiconductor device 100.

In some embodiments, the plurality of epitaxial layers is formed with gradient thicknesses. In some embodiments, each epitaxial layer of one, some, or all of the plurality of epitaxial layers is formed to have a greater thickness than an underlying layer, such as another epitaxial layer of the plurality of epitaxial layers that underlies the epitaxial layer. In some embodiments, at least one of (i) the second thickness 504 of the second epitaxial layer 502 is greater than the first thickness 404 of the first epitaxial layer 402, (ii) the third thickness 604 of the third epitaxial layer 602 is greater than the second thickness 504 of the second epitaxial layer 502, or (iii) the fourth thickness 704 of the fourth epitaxial layer 702 is greater than the third thickness 604 of the third epitaxial layer 602. In some embodiments, an uppermost epitaxial layer of the plurality of epitaxial layers has a thickness of at least 3 micrometers, such as a thickness of at least 5 micrometers or a thickness of at least 5.5 micrometers. In some embodiments, the uppermost epitaxial layer of the plurality of epitaxial layers is the fourth epitaxial layer 702, wherein the fourth thickness 704 (shown in FIG. 7) of the fourth epitaxial layer 702 is at least 3 micrometers, at least 5 micrometers, or at least 5.5 micrometers. In some embodiments, the thickness 204 of the poly layer 202 is based upon the thickness of the uppermost epitaxial layer (e.g., the fourth thickness 704 of the fourth epitaxial layer 702) of the plurality of epitaxial layers. In some embodiments, the thickness 204 of the poly layer 202 is at most about equal to the thickness of the uppermost epitaxial layer of the plurality of epitaxial layers.

In some embodiments, the substrate 102 and the plurality of epitaxial layers comprise silicon or other suitable material. In some embodiments, the first conductivity type is p-type and the second conductivity type is n-type. In some embodiments, each epitaxial layer of at least some of the plurality of epitaxial layers comprises p-type dopants comprising at least one of boron dopants, aluminum dopants, gallium dopants, beryllium dopants, or other p-type dopants. In some embodiments, a first p-type dopant concentration of p-type dopants in the first epitaxial layer 402 is greater than a second p-type dopant concentration of p-type dopants in the second epitaxial layer 502. In some embodiments, the second p-type dopant concentration of p-type dopants in the second epitaxial layer 502 is greater than a third p-type dopant concentration of p-type dopants in the third epitaxial layer 602. In some embodiments, the third p-type dopant concentration of p-type dopants in the third epitaxial layer 602 is greater than a fourth p-type dopant concentration of p-type dopants in the fourth epitaxial layer 702. In some embodiments, the fourth p-type dopant concentration corresponds to an average concentration of p-type dopants across at least a portion of the fourth epitaxial layer 702. In some embodiments, a p-type dopant concentration of p-type dopants in the second doped region 1102 is greater than at least one of the first p-type dopant concentration, the second p-type dopant concentration, the third p-type dopant concentration, or the fourth p-type dopant concentration. In some embodiments, a p-type dopant concentration of p-type dopants in the substrate 102 is greater than a p-type dopant concentration of p-type dopants in each epitaxial layer of the plurality of epitaxial layers. In some embodiments, the p-type dopant concentration of p-type dopants in the substrate 102 is greater than at least one of the first p-type dopant concentration, the second p-type dopant concentration, the third p-type dopant concentration, or the fourth p-type dopant concentration.

In some embodiments, the substrate 102 comprises first bulk micro defects (BMDs). In some embodiments, the semiconductor device 100 comprising the poly layer 202 provides for an increase in an amount of the first BMDs in the substrate 102, as compared with a semiconductor device formed without the poly layer 202. In some embodiments, the first BMDs are formed in the substrate 102 as a result of at least one of (i) thermal energy introduced to at least some of the semiconductor device 100 during a first process performed to form the poly layer 202, (ii) thermal energy introduced to at least some of the semiconductor device 100 during one or more second processes performed to form one, some or all of the plurality of epitaxial layers, or (iii) thermal energy applied to at least some of the semiconductor device 100 during one or more third processes performed on the semiconductor device 100. In some embodiments, the first process comprises a high-temperature process (e.g., a high-temperature deposition process, high-temperature growth process, etc.) in which at least some of the semiconductor device 100 is heated to a temperature higher than a first threshold temperature. In some embodiments, heating at least some of the semiconductor device 100 to a temperature higher than the first threshold temperature causes formation of at least some of the first BMDs in the substrate 102. In some embodiments, each of one, some, or all of the one or more second processes comprises a high-temperature process (e.g., a high-temperature epitaxial process) in which at least some of the semiconductor device 100 is heated to a temperature higher than the first threshold temperature.

In some embodiments, the amount of the first BMDs in the substrate 102 is a function of a thickness of an epitaxial layer of the plurality of epitaxial layers, such as at least one of the first thickness 404 of the first epitaxial layer 402, the second thickness 504 of the second epitaxial layer 502, the third thickness 604 of the third epitaxial layer 602, the fourth thickness 704 of the fourth epitaxial layer 702, etc. In some embodiments, an increase of the thickness of the epitaxial layer results in an increase of the amount of the first BMDs in the substrate 102, such as due, at least in part, to an increase in an amount of processing time and/or an amount of thermal energy associated with forming (via epitaxial growth, for example) the epitaxial layer to have the increased thickness. In some embodiments, the thickness of the epitaxial layer is configured based upon the thickness 204 of the poly layer 202. In some embodiments, the thickness of the epitaxial layer is at least about equal to the thickness 204 of the poly layer 202. In some embodiments, the thickness of the uppermost epitaxial layer of the plurality of epitaxial layers, such as the fourth thickness 704 of the fourth epitaxial layer 702 or other epitaxial layer over the fourth epitaxial layer 702, is at least about equal to the thickness 204 of the poly layer 202. In some embodiments, the thickness of the uppermost epitaxial layer being at least about equal to the thickness 204 of the poly layer 202 provides for a sufficient amount of the first BMDs in the substrate 102 (for improved metal gettering of the semiconductor device 100, for example).

In some embodiments, the amount of the first BMDs in the substrate 102 is a function of a substrate thickness 1210 of the substrate 102. In some embodiments, an increase of the substrate thickness 1210 of the substrate 102 results in a decrease of the amount of the first BMDs in the substrate 102. In some embodiments, a decrease of the substrate thickness 1210 of the substrate 102 results in an increase of the amount of the first BMDs in the substrate 102. In some embodiments, the substrate thickness 1210 of the substrate 102 is configured based upon the thickness 204 of the poly layer 202. In some embodiments, the thickness 204 of the poly layer 202 is configured based upon the substrate thickness 1210 of the substrate 102. The substrate thickness 1210 of the substrate 102 is between about 0.5 times the thickness 204 of the poly layer 202 to about 3 times the thickness 204 of the poly layer 202. Other relationships between the substrate thickness 1210 of the substrate 102 and the thickness 204 of the poly layer 202 are within the scope of the present disclosure. The substrate thickness 1210 of the substrate 102 is at least one of (i) at least about 250 angstroms, or (ii) at least about 500 angstroms. Other values of the substrate thickness 1210 of the substrate 102 are within the scope of the present disclosure.

In some embodiments, the semiconductor device 100 comprising the poly layer 202 provides for improved metal gettering of the semiconductor device 100, as compared with a semiconductor device formed without the poly layer 202. In some embodiments, the improved metal gettering of the semiconductor device 100 is due, at least in part, to the increase in the amount of the first BMDs in the substrate 102. In some embodiments, the semiconductor device 100 comprising the poly layer 202 provides for a reduced amount of metal contaminants in a first portion of the semiconductor device 100, as compared with a semiconductor device formed without the poly layer 202. In some embodiments, the first portion comprises (i) at least a portion of the uppermost epitaxial layer (e.g., the fourth epitaxial layer 702) of the plurality of epitaxial layers, (ii) a top surface of the uppermost epitaxial layer (e.g., the top surface of the fourth epitaxial layer 702), (iii) at least a portion of the photodiode 1204, (iv) at least a portion of the p-n junction 1206, (v) at least a portion of the intrinsic region, or (vi) at least a portion of one or more epitaxial layers under the uppermost epitaxial layer (e.g., at least one of the first epitaxial layer 402, the second epitaxial layer 502, the third epitaxial layer 602, etc.).

In some embodiments, first metal contaminants travel from a second portion of the semiconductor device 100 to the first portion. In some embodiments, the first metal contaminants comprise at least one of metal ions, metal particles, etc. In some embodiments, the second portion comprises at least one of (i) a portion, of the semiconductor device 100, that underlies the first portion, (ii) at least a portion of the substrate 102, (iii) at least a portion of one or more layers underlying the substrate 102, or (iv) one or more other portions of the semiconductor device 100. In some embodiments, at least some of the first metal contaminants are driven and/or urged from the second portion towards the first portion by one or more fourth processes, such as one or more semiconductor fabrication processes performed for fabrication of the semiconductor device 100. In some embodiments, each of one, some or all of the one or more fourth processes comprises a high-temperature process in which at least some of the semiconductor device 100 is heated to a temperature higher than a second threshold temperature. In some embodiments, heating at least some of the semiconductor device 100 to a temperature higher than the second threshold temperature causes metal contaminants to migrate towards and/or into the second portion, such as at least one of in a second direction opposite to the first direction 1006 (shown in FIG. 10) or in a different direction. In some embodiments, the one or more fourth processes comprise one or more epitaxial processes performed to form one, some, or all of the plurality of epitaxial layers. In some embodiments, at least some of the first metal contaminants originate from metal components (e.g., metal vias, metal interconnects, etc.) formed in at least one of the substrate 102, a metal interconnect layer, or other layer of the semiconductor device 100. In some embodiments, at least some of the first metal contaminants are introduced to the semiconductor device 100 from a semiconductor fabrication tool used to perform a semiconductor fabrication process for fabrication of the semiconductor device 100. In some embodiments, at least some of the first metal contaminants are introduced to the semiconductor device 100 from a semiconductor processing environment in which the semiconductor device 100 is disposed, such as a chamber of the semiconductor fabrication tool or a wafer storage device.

In some embodiments, metal contaminants in the first portion of the semiconductor device 100 produces noise in the semiconductor device 100 (e.g., an image sensor) that decreases a quality and/or accuracy of the first image generated using the semiconductor device 100. In some embodiments, metal contaminants in the first portion act as electron sources which release electrons that are recorded and/or measured by the first read out circuit, thereby introducing at least one of noise, inaccuracies, etc. to metrics (e.g., the first metric) determined using the first read out circuit and/or images (e.g., the first image) generated using the semiconductor device 100. In some embodiments, metal contaminants in the first portion mitigate and/or inhibit passage of photons to the photodiode 1204 and/or the p-n junction 1206, thereby reducing an accuracy of images (e.g., the first image) generated using the semiconductor device 100 and/or reducing a sensitivity of the semiconductor device 100. Thus, the reduced amount of metal contaminants in the first portion of the semiconductor device 100 using the techniques provided herein provides for at least one of improved accuracy, reduced noise, increased sensitivity, improved white pixel performance, etc. of the semiconductor device 100 (e.g., the image sensor).

In some embodiments, the reduced amount of metal contaminants in the first portion is due, at least in part, to the increase in the amount of the first BMDs in the substrate 102. In some embodiments, BMDs in the semiconductor device 100 (e.g., the first BMDs in the substrate 102) mitigate and/or inhibit migration of metal contaminants from the second portion of the semiconductor device 100 to the first portion. In some embodiments, metal contaminants are trapped in BMDs in the semiconductor device 100 (e.g., the first BMDs in the substrate 102 trap metal contaminants such that the metal contaminants cannot travel to the first portion). In some embodiments, the reduced amount of metal contaminants in the first portion is due, at least in part, to the poly layer 202 mitigating and/or inhibiting migration of metal contaminants from the second portion of the semiconductor device 100 to the first portion. In some embodiments, metal contaminants are trapped in the poly layer 202.

In some embodiments, the thickness 204 of the poly layer 202 is at least a threshold thickness. The threshold thickness is at least one of (i) between about 500 angstroms to about 1500 angstroms, or (ii) about 1000 angstroms. Other values of the threshold thickness are within the scope of the present disclosure. In some embodiments, compared with the thickness 204 being less than the threshold thickness, the thickness 204 being greater than the threshold thickness provides for, at least, increased BMDs and (i) improved metal gettering of the semiconductor device 100, (ii) reduced metal contaminants in the first portion of the semiconductor device 100, or (iii) improved accuracy, sensitivity and/or white pixel performance of the image sensor.

In some embodiments, the amount of the first BMDs in the substrate 102 is at least a threshold amount of BMDs. The threshold amount of BMDs corresponds to at least one of (i) a threshold BMD density between about 1×10\hat{ }7 ea/centimeters (cm)³ to about 1×10\hat{ }9 ea/cm³, or (ii) a threshold BMD density of about 1×10\hat{ }8 ea/cm³. Other values of the threshold amount of BMDs are within the scope of the present disclosure. In some embodiments, a BMD density is determined based upon a count of BMDs (determined by microscope inspection, for example). In some embodiments, compared with the amount of the first BMDs in the substrate 102 being less than the threshold amount of BMDs, the amount of the first BMDs in the substrate 102 being greater than the threshold amount of BMDs provides for (i) improved metal gettering of the semiconductor device 100, (ii) reduced metal contaminants in the first portion of the semiconductor device 100, or (iii) improved accuracy, sensitivity and/or white pixel performance of the image sensor.

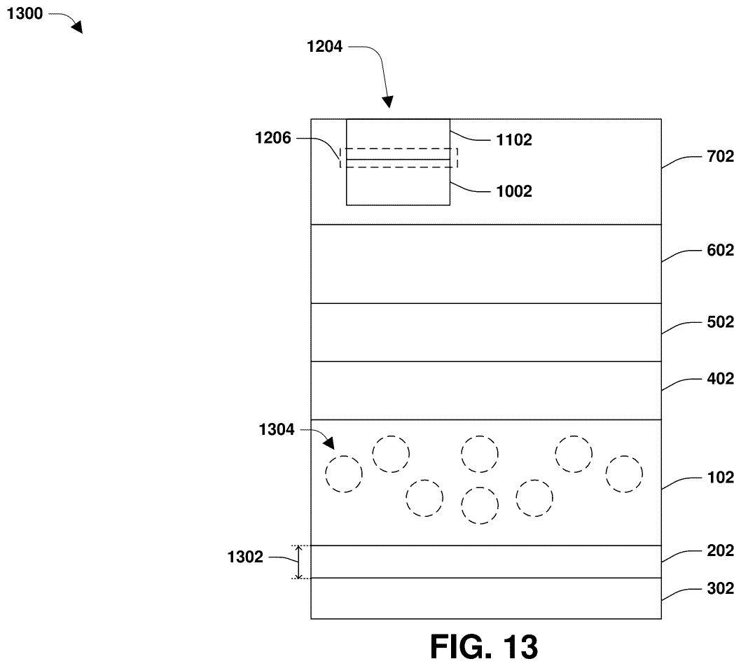

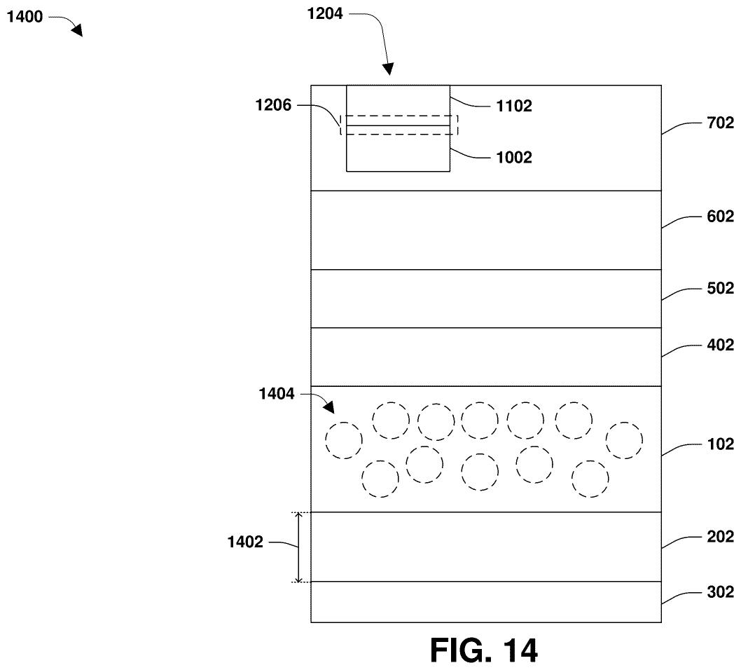

FIGS. 13 and 14 illustrate cross-sectional views of different versions of the semiconductor device 100, in accordance with some embodiments. FIG. 13 illustrates a first version 1300 of the semiconductor device 100 in which the poly layer 202 has a first poly layer thickness 1302. FIG. 14 illustrates a second version 1400 of the semiconductor device 100 in which the poly layer 202 has a second poly layer thickness 1402 greater than the first poly layer thickness 1302. In some embodiments, due to the second poly layer thickness 1402 of the second version 1400 of the semiconductor device 100 being greater than the first poly layer thickness 1302 of the first version 1300 of the semiconductor device 100, the substrate 102 of the second version 1400 of the semiconductor device 100 has an greater amount of BMDs 1404 (shown in FIG. 14 as dashed-line circles) in comparison with an amount of BMDs 1304 (shown in FIG. 13 as dashed-line circles) in the substrate 102 of the first version 1300 of the semiconductor device 100. In some embodiments, in comparison with the first version 1300 of the semiconductor device 100, the second version 1400 of the semiconductor device 100 has at least one of (i) improved metal gettering, (ii) reduced metal contaminants in the first portion, or (iii) improved accuracy, sensitivity and/or white pixel performance of the image sensor, such as due, at least in part, to the greater amount of the BMDs 1404.

According to some embodiments, at least one of the relative dimensions, thicknesses, dopant concentrations, dopant gradients, etc. associated with at least one of one or more layers, features, etc. mentioned herein, such as at least one of epitaxial layers, doped regions, etc. are important (e.g., critical) because they facilitate at least one of (i) improved metal gettering, (ii) reduced metal contaminants in the first portion, or (iii) improved accuracy, sensitivity and/or white pixel performance of the image sensor, such as by, at least, inhibiting, mitigating, etc. the presence of metal contaminants in the first portion, such as by inhibiting, mitigating, etc. movement, migration, etc. of metal contaminants to the first portion, such as from the second portion.

In some embodiments, a semiconductor device is provided. The semiconductor device includes a poly layer. The semiconductor device includes a substrate over the poly layer. The semiconductor device includes a first epitaxial layer over the substrate. The semiconductor device includes a second epitaxial layer over the first epitaxial layer. The semiconductor device includes a photodiode in at least one of the first epitaxial layer or the second epitaxial layer.

In some embodiments, a method of forming a semiconductor device is provided. The method includes forming a poly layer at a first side of a substrate. The method includes forming a first epitaxial layer over the substrate, wherein the substrate is between the first epitaxial layer and the poly layer. The method includes forming a second epitaxial layer over the first epitaxial layer. The method includes forming a photodiode in at least one of the first epitaxial layer or the second epitaxial layer.

In some embodiments, a semiconductor device is provided. The semiconductor device includes a poly layer. The semiconductor device includes a substrate over the poly layer. The semiconductor device includes an epitaxial layer over the substrate, wherein a thickness of the poly layer is less than a thickness of the epitaxial layer. The semiconductor device includes a photodiode in the epitaxial layer.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A semiconductor device, comprising:
a poly layer;
a substrate over the poly layer;
a first epitaxial layer over the substrate;
a second epitaxial layer over the first epitaxial layer; and
a photodiode in at least one of the first epitaxial layer or the second epitaxial layer.

2. The semiconductor device of claim 1, wherein:
the poly layer comprises polysilicon.

3. The semiconductor device of claim 1, comprising:
an oxide layer under the poly layer.

4. The semiconductor device of claim 1, wherein:
a first thickness of the first epitaxial layer is less than a second thickness of the second epitaxial layer.

5. The semiconductor device of claim 1, wherein:
the substrate comprises first dopants having a first conductivity type;
the first epitaxial layer comprises second dopants having the first conductivity type;
the second epitaxial layer comprises third dopants having the first conductivity type; and
the photodiode comprises:
a first doped region comprising fourth dopants having a second conductivity type different than the first conductivity type; and
a second doped region, over the first doped region, comprising fifth dopants having the first conductivity type.

6. The semiconductor device of claim 5, wherein the photodiode comprises:
a p-n junction between the first doped region and the second doped region.

7. The semiconductor device of claim 5, wherein the photodiode comprises:
an intrinsic region between the first doped region and the second doped region.

8. The semiconductor device of claim 5, wherein:
a first concentration of the second dopants in the first epitaxial layer is greater than a second concentration of the third dopants in the second epitaxial layer.

9. A method of forming a semiconductor device, comprising:
forming a poly layer at a first side of a substrate;
forming a first epitaxial layer over the substrate, wherein the substrate is between the first epitaxial layer and the poly layer;
forming a second epitaxial layer over the first epitaxial layer; and
forming a photodiode in at least one of the first epitaxial layer or the second epitaxial layer.

10. The method of claim 9, wherein:
the substrate comprises first dopants having a first conductivity type;
forming the first epitaxial layer comprises forming the first epitaxial layer to comprise second dopants having the first conductivity type;
forming the second epitaxial layer comprises forming the second epitaxial layer to comprise third dopants having the first conductivity type; and
forming the photodiode comprises:
forming a first doped region to comprise fourth dopants having a second conductivity type in at least one of the first epitaxial layer or the second epitaxial layer, wherein the second conductivity type is different than the first conductivity type; and
forming a second doped region to comprise fifth dopants having the first conductivity type in at least one of the first epitaxial layer or the second epitaxial layer, wherein the second doped region is over the first doped region.

11. The method of claim 9, wherein:
the substrate comprises a first concentration of first dopants having a first conductivity type;
forming the first epitaxial layer comprises forming the first epitaxial layer to comprise a second concentration of second dopants having the first conductivity type; and
forming the second epitaxial layer comprises forming the second epitaxial layer to comprise a third concentration of third dopants having the first conductivity type, wherein the second concentration is greater than the third concentration.

12. The method of claim 9, wherein forming the first epitaxial layer comprises:
forming the first epitaxial layer to have a first thickness that is less than a second thickness of the second epitaxial layer.

13. The method of claim 9, wherein forming the poly layer comprises:
forming the poly layer to comprise polysilicon.

14. A semiconductor device, comprising:
a poly layer;
a substrate over the poly layer;
an epitaxial layer over the substrate, wherein a thickness of the poly layer is less than a thickness of the epitaxial layer; and
a photodiode in the epitaxial layer.

15. The semiconductor device of claim 14, wherein:
the poly layer comprises polysilicon.

16. The semiconductor device of claim 14, comprising:
an oxide layer under the poly layer.

17. The semiconductor device of claim 14, wherein:
the substrate comprises first dopants having a first conductivity type;
the epitaxial layer comprises second dopants having the first conductivity type; and
the photodiode comprises:
a first doped region comprising third dopants having a second conductivity type different than the first conductivity type; and
a second doped region, over the first doped region, comprising fourth dopants having the first conductivity type.

18. The semiconductor device of claim 17, wherein the photodiode comprises:
a p-n junction between the first doped region and the second doped region.

19. The semiconductor device of claim 17, wherein the photodiode comprises:
an intrinsic region between the first doped region and the second doped region.

20. The semiconductor device of claim 17, wherein:
the first conductivity type is p-type; and
the second conductivity type is n-type.
